(19) United States
(12) Patent Application Publication
(10) Pub. No.: US 2026/0118461 A1
(43) Pub. Date: Apr. 30, 2026

(54) Method for Multispectral Magnetic Resonance Imaging

(71) Applicant: Siemens Healthineers AG, Forchheim (DE)

(72) Inventor: Mathias Nittka, Baiersdorf (DE)

(73) Assignee: Siemens Healthineers AG, Forchheim (DE)

(21) Appl. No.: 19/372,524

(22) Filed: Oct. 29, 2025

(30) Foreign Application Priority Data
Oct. 30, 2024 (DE) 10 2024 210 449.3

(51) Int. Cl. G01R 33/56; G01R 33/565

(52) U.S. Cl. CPC G01R 33/5608; G01R 33/56554

(57) ABSTRACT

The disclosure relates to multispectral magnetic resonance imaging which includes capturing raw data at raw data points of a raw data space of a plurality of three-dimensional spectral volumes, said spectral volumes each differing at least in their frequency range used for excitation, the raw data comprising a plurality of raw data sets, in each case a raw data set is in each case to be assigned to a spectral volume, each raw data set comprises raw data of a raw data space corresponding to a sampling pattern, and the sampling patterns for raw data sets of in each case two spectrally adjacent spectral volumes are different from one another; and providing the raw data comprising the plurality of raw data sets.

### CROSS-REFERENCE TO RELATED APPLICATIONS

The present application claims priority to and the benefit of Germany patent application no. DE 10 2024 210 449.3, filed on Oct. 30, 2024, the contents of which are incorporated herein by reference in their entirety.

### TECHNICAL FIELD

The disclosure relates to a method, a magnetic resonance device, a computer program product, and an electronically readable data carrier for multispectral magnetic resonance imaging.

### BACKGROUND

In a magnetic resonance device, the body to be examined of an object, e.g. a patient, is usually exposed to a relatively high main magnetic field, for example of 1.5 or 3 or 7 tesla, via a main magnet. In addition, gradient pulses are output via a gradient coil unit. High-frequency radio-frequency pulses, for example excitation pulses, are then emitted via a radio-frequency antenna unit by means of suitable antenna facilities, resulting in the nuclear spins of particular atoms resonantly excited by these radio-frequency pulses being tilted by a defined flip angle compared to the magnetic field lines of the main magnetic field. During the relaxation of the nuclear spins, radio-frequency signals, known as magnetic resonance signals (MR signals), are emitted, and are received by means of suitable radio-frequency antennas and then further processed. The desired image data can finally be reconstructed from the raw data acquired in this way.

Hence for a particular measurement a particular magnetic resonance control sequence (MR control sequence), also called a pulse sequence, is to be emitted, which consists of a sequence of radio-frequency pulses, for example excitation pulses and refocusing pulses, as well as gradient pulses suitably coordinated thereto that are to be emitted, in different gradient axes along different spatial directions. Suitably timed for this purpose, readout windows are set which specify the periods in which the induced magnetic resonance signals are captured. Typically, such a measurement is carried out in what is known as the examination area, i.e. a sub-area of the object under examination.

The data space in which the MR signals are present is referred to as a “raw data space.” The MR signals are digitalized and stored as complex numerical values at raw data points of the raw data space as raw data. From the raw data, associated image data can for example be reconstructed by means of a multidimensional Fourier transform. Typically, raw data is not acquired from all raw data points of the raw data space, but a selection of raw data points is made, determined by a sampling pattern. Data from raw data points at which no raw data is acquired can be compensated for by means of various techniques, such as for example partial Fourier or parallel imaging. If, for example, a sampling pattern provides for the acquisition of raw data at every fourth raw data point, this is referred to as “undersampling” by a factor of four.

If an object under examination has a metal implant, such as a knee or hip implant for example, this causes inhomogeneities of the main magnetic field due to differences in susceptibility between the metal of the implant and the surrounding tissue. The inhomogeneities of the main magnetic field cause an excited slice to be spatially distorted in the slice selection direction and/or spins outside the frequency range of the excitation pulse are not excited and thus no MR signals are emitted. Without further correction, this would result in signal losses and distortions of the reconstructed image data.

These artifacts can be reduced or compensated for by means of multispectral magnetic resonance imaging. For this, use is made of MR control sequences which on the basis of spin echoes and for the generation of the MR signals excite the area under examination with excitation pulses in different frequency ranges, which capture corresponding MR signals of the area under examination for each frequency range and combine them to form image data of the area under examination. Examples of such methods for multispectral magnetic resonance imaging are disclosed in US 2010/0033179 A1 with slice-selective excitation or in US 2013/0278254 A1 without slice-selective excitation.

The multispectral magnetic resonance imaging provides that excitation pulses with different frequency ranges are used, wherein for each frequency range the MR signals of a three-dimensional volume are captured. In this case, phase-encoding typically takes place in two phase-encoding directions perpendicular to one another and frequency-encoding in a further spatial direction. This three-dimensional volume can correspond to the area under examination or a sub-area of the area under examination and because of the dependency on the frequency range of the excitation pulse can be referred to as a spectral volume. In the context of multispectral magnetic resonance imaging, raw data from multiple spectral volumes is consequently acquired, wherein each spectral volume is to be assigned a frequency range, said multiple spectral volumes then being combined and reconstructed to form image data. Because of the dependency of the spectral volumes on the frequency range of the excitation pulse, the multispectral magnetic resonance imaging can be regarded as a four-dimensional view, wherein the spectral direction given by the different frequency ranges can be viewed as a fourth dimension.

### SUMMARY

The acquisition of multispectral MR signals is time-consuming. The object of the disclosure is to specify an accelerated and robust method for multispectral magnetic resonance imaging. The object is achieved by the various embodiments described herein, including the claims.

In an embodiment, a method for multispectral magnetic resonance imaging starts with the capture of raw data at raw data points of a raw data space of a plurality of three-dimensional spectral volumes, said spectral volumes each differing at least in their frequency range used for the excitation. The raw data comprises a plurality of raw data sets, wherein in each case one raw data set of the plurality of raw data sets is in each case to be assigned to a spectral volume of the plurality of spectral volumes, each raw data set comprises raw data of a raw data space corresponding to a sampling pattern, and the sampling patterns for raw data sets of in each case two spectrally adjacent spectral volumes are different from one another. A further method step entails the provision of the raw data comprising the plurality of raw data sets.

The raw data can consequently be divided into multiple raw data sets and/or can consist of multiple raw data sets. The sampling patterns of all raw data sets typically provide for undersampling in a peripheral area of the raw data space. The sampling patterns of all raw data sets typically comprise raw data points in a peripheral area of the raw data space. The capture of the raw data can include an acquisition of the raw data, e.g. the plurality of raw data sets. For example, the capture of the raw data can include an output of selective or non-selective excitation pulses and/or an acquisition of the raw data of the raw data space corresponding to the sampling pattern assigned to the spectral volume. For this purpose, a corresponding MR control sequence for each raw data set and/or for each spectral volume can provide an excitation pulse with an individually defined frequency range and an individual sampling pattern of the raw data space. Typically, the frequency ranges of the excitation pulses for the plurality of spectral volumes are in each case different from one another. The capture of the raw data can include retrieving the raw data from a storage medium and/or accessing the raw data. The provision of the raw data can comprise an output and/or storage and/or transfer of the raw data. The raw data can be referred to as multispectral raw data.

The frequency ranges used for excitation are typically equidistant and/or consecutive in the spectral direction. The frequency ranges used for excitation can at least partially overlap. The frequency ranges used for excitation are typically defined by the shape and carrier frequency and/or center frequency of the excitation pulse used. The frequency ranges of all spectral excitation pulses used for excitation typically indicate the total frequency range which is covered in the context of multispectral magnetic resonance imaging. Spectrally adjacent spectral volumes are typically characterized in that the frequency ranges of the correspondingly used excitation pulses are adjacent in the spectral direction and e.g. are consecutive and/or overlap. For instance, the center frequencies of the frequency ranges of spectrally adjacent spectral volumes are successive center frequencies in the spectral direction.

The method provides for a diverse undersampling of adjacent spectral volumes. In the context of a classic and separate reconstruction of individual raw data sets, this would lead to incoherent artifacts in adjacent spectral volumes without taking into account the sampling patterns. This incoherence can be combined with the existing similarities of adjacent spectral volumes particularly efficiently, for example by means of sparse transformations. The provided raw data can therefore be reconstructed even if the sampling patterns of the individual raw data sets provide for a high rate of undersampling. This e.g. enables fast acquisition of raw data, e.g. multispectral raw data, which nevertheless can be reconstructed to form high-quality image data.

One form of embodiment of the method provides that the sampling patterns for the raw data sets provide for undersampling in two phase-encoding directions with a phase offset in one phase-encoding direction of the two phase-encoding directions and a phase offset in one spectral direction, wherein the spectral direction corresponds to the spectral sequence of the spectral volumes. The sampling patterns for all raw data sets may for example correspond to this form of embodiment. This form of embodiment of the sampling patterns may for example apply to the peripheral area of the raw data space. The sampling patterns for the raw data sets in accordance with this form of embodiment may provide a full sampling of the central area of the raw data space. A phase offset can correspond to a shift and/or an offset of the sampling pattern, e.g. of the raster for an undersampling. A phase offset typically corresponds to a shift of defined rows of the raw data space by a defined number of raw data points. A sampling pattern with a phase offset typically provides that adjacent rows of the raw data space, said rows not being blank rows and being free from sampling, are sampled differently from one another. A sampling pattern with a phase offset may be configured like a chessboard, wherein additional blank rows free from sampling can be inserted symmetrically. The sampling pattern for 2D CAIPIRINHA for two phase-encoding directions known from Breuer et. al, Controlled aliasing in volumetric parallel imaging (2D CAIPIRINHA), Magn. Reson. Med. 2006 March; 55(3): 549-56 can for example be used in accordance with this form of embodiment as the basis for expansion to the spectral direction as a third dimension.

This form of embodiment therefore provides for a phase offset in the spectral direction, wherein the raw data sets of spectrally adjacent volumes have a sampling pattern which is offset to one another and/or shifted and/or complementary to one another. Redundant information in the spectral direction, for example because of partially overlapping frequency ranges and/or partially overlapping spectral volumes and/or little frequency-dependent raw data, can in accordance with this form of embodiment, because of the complementary raw data sets, be used particularly efficiently in the context of reconstruction for the reduction of artifacts.

This form of embodiment generates phase shifts in a phase-encoding direction and in the spectral direction, resulting in a particular incoherence. This enables the use of different reconstruction methods for the combined reconstruction of multiple spectral volumes by exploiting the incoherence with adjacent spectral volumes.

One form of embodiment of the method provides that the sampling patterns in a peripheral area of the raw data space of the different raw data sets in the spectral direction corresponding to the spectral sequence of the spectral volumes differ from one another by a translation in the raw data space. In accordance with this form of embodiment the sampling patterns of the raw data sets in a spectral sequence have an offset to one another and/or are congruent to one another, e.g. in the peripheral area of the raw data space. This form of embodiment enables a systematic sampling of the raw data space and the use of adapted reconstruction methods.

One form of embodiment of the method provides that the sampling patterns for the raw data sets in a first phase-encoding direction of the raw data space provide for an undersampling by the factor M and in a second phase-encoding direction of the raw data space an undersampling by the factor N and the sampling patterns for spectrally adjacent spectral volumes in the first phase-encoding direction are shifted to one another by N/P and/or in the second phase-encoding direction by M/P raw data points, where N, M and P are integers.

The sampling patterns for all raw data sets may e.g. correspond to the rules of this form of embodiment. The sampling patterns for spectrally adjacent spectral volumes typically relate to sampling patterns of the raw data sets assigned to the spectral volumes.

The sampling patterns in the first phase-encoding direction may e.g. be shifted to one another by N/P or in the second phase-encoding direction by M/P. In accordance with this form of embodiment the sampling pattern corresponding to the spectral sequence of the spectral volumes can correspond to a sampling pattern of 2D CAIPIRINHA. This form of embodiment consequently provides for a continuous and repetitive offset of the sampling patterns in the spectral direction. This enables the use of different reconstruction methods for the combined reconstruction of multiple spectral volumes by exploiting the incoherence in adjacent spectral volumes.

One form of embodiment of the method provides that P sampling patterns different from one another are provided for the raw data space, which repeat in the spectral direction corresponding to the spectral sequence after P spectral volumes. P is an integer. With P=2 in accordance with this form of embodiment the sampling patterns for raw data sets for spectrally adjacent volumes are formed in an alternating manner. This enables the use of different reconstruction methods for the combined reconstruction of multiple spectral volumes by exploiting the incoherence in adjacent spectral volumes.

One form of embodiment of the method provides that the sampling patterns of the raw data sets in a peripheral area of the raw data space provide for an undersampling by any suitable factor, for example of at least four, at least six, at least eight, etc. This enables a high acceleration of the acquisition of the raw data. For instance, a combined reconstruction of the raw data taking into account multiple raw data sets can execute such a high acceleration with low losses.

One form of embodiment of the method provides that the sampling patterns of the raw data sets in a peripheral area of the raw data space provide for an undersampling by an identical factor. The peripheral area typically comprises at least 80% of the raw data space and excludes a central area of the raw data space. The central area is typically a circle and/or rectangle surrounding the center of the raw data space. The central area can for example in each case comprise eight raw data points, thus in total 64 raw data points, in both phase-encoding directions. The sampling patterns of the raw data sets typically provide for full sampling in the central area of the raw data space. This form of embodiment enables a uniformly high acceleration of the acquisition of the raw data, wherein the raw data is evenly distributed among different raw data sets. For instance, a combined reconstruction of the raw data taking into account multiple raw data sets can execute such a high acceleration with low losses.

One form of embodiment of the method provides that the sampling patterns of the raw data sets provide for an undersampling by a factor different by a maximum of one in a peripheral area of the raw data space. Also in accordance with this form of embodiment, the acceleration of the acquisition of the raw data is approximately evenly distributed among the different raw data sets.

One form of embodiment of the method provides that the sampling patterns of the raw data sets provide for an undersampling in a central area of the raw data space. Typically, the central area of the raw data space in the context of an acquisition of the raw data for purposes of calibration is captured in full, e.g. in classic, non-multispectral magnetic resonance imaging. Due to undersampling of the raw data space, the acquisition of the raw data can be additionally accelerated. Because of a redundancy of raw data, e.g. when spectrally adjacent spectral volumes overlap, this redundancy can be exploited in a combined reconstruction of the raw data taking into account multiple raw data sets, as a result of which such an acceleration is enabled.

One form of embodiment of the method additionally comprises a reconstruction of the raw data to form image data, wherein for the spectral volumes in each case spectral image data sets are reconstructed and the spectral image data sets are combined to form image data. The reconstruction of the raw data to form image data consequently comprises a reconstruction of individual spectral image data sets, wherein a spectral image data set may be reconstructed for each spectral volume. This reconstruction typically comprises a Fourier transform. Furthermore, the reconstruction of the raw data to form image data then comprises a combination of the spectral image data sets to form image data, wherein the combination typically takes place in the image space, e.g. not in the raw data space. Such image data can be referred to as multispectral image data. This form of embodiment can additionally comprise provision, e.g. storage and/or visualization, of the image data. This form of embodiment ensures an efficient merging of the plurality of raw data sets, so that redundant information, for example from overlapping spectral volumes, can be used for the reconstruction of the spectral image data sets. This in turn allows a higher acceleration and undersampling when capturing the raw data and thus enables particularly efficient multispectral magnetic resonance imaging.

One form of embodiment of the method provides that the reconstruction of a spectral image data set for a spectral volume is carried out taking into account the raw data sets assigned to the spectral volume and the at least one spectrally adjacent spectral volume. In accordance with this form of embodiment the reconstruction of a spectral image data set is consequently based on the raw data set of the spectral volume and at least the raw data set of one adjacent spectral volume. The reconstruction of a spectral image data set for a spectral volume may be carried out taking into account all raw data sets. Typically, the reconstructions of all spectral image data sets are carried out taking into account the raw data sets assigned to the spectral volume and the at least two spectrally adjacent spectral volumes, providing that spectrally adjacent spectral volumes exist. This form of embodiment ensures that a redundancy in raw data sets of adjacent and/or other frequency ranges is already used for the reconstruction of spectral image data sets, which enables higher undersampling and thus accelerated acquisition of the raw data.

One form of embodiment of the method provides that the reconstruction of a spectral image data set is carried out using compressed sensing and/or a sparse transformation in the spectral direction and/or a trained function. The sparse transformation can be designed as a wavelet transformation. The trained function can be designed as a neural network. The raw data acquired in the context of the multispectral magnetic resonance imaging typically has a redundancy in the spectral direction, for example caused by spectrally overlapping spectral volumes. This redundancy in the spectral direction can be exploited by compressed sensing in the context of an iterative reconstruction, as described in Ye, J. C. Compressed sensing MRI: a review from signal processing perspective. BMC biomed eng. 1, 8 (2019). This method works particularly well with varying sampling patterns in the sparse, i.e. the spectral, direction, since such sampling patterns result in incoherent artifacts in conventionally reconstructed image data. The use of compressed sensing for the reconstruction of the spectral image data sets is consequently particularly advantageous in combination with a sampling pattern analogous to 2D CAIPIRINHA with an extension in the spectral direction, e.g. with phase offset in the spectral direction.

One form of embodiment of the method provides that the reconstruction of a spectral image data set is carried out using a reconstruction method of parallel imaging. This form of embodiment is advantageous, providing that the sampling patterns of the different raw data sets in the spectral direction corresponding to the spectral sequence of the spectral volumes differ from one another by a translation in the raw data space. This form of embodiment is particularly advantageous if the sampling patterns for the raw data sets provide for undersampling in two phase-encoding directions with a phase offset in one phase-encoding direction of the two phase-encoding directions and a phase offset in one spectral direction, wherein the spectral direction corresponds to the spectral sequence of the spectral volumes.

In parallel imaging, a local redundancy of the sensitivities of the receiving coils is typically used in reconstruction to compensate for missing data. In accordance with this form of embodiment, additionally and/or alternatively the spectral redundancy of spectrally adjacent spectral volumes in the spectral dimension is exploited. Thus GRAPPA can for example be used in the spectral dimension. Providing that the sampling pattern of 2D CAIPIRINHA is used and extended by the spectral dimension, a CAIPIRINHA reconstruction method may be used to reconstruct the spectral image data sets in accordance with this form of embodiment. This enables use of a particularly sparse sampling pattern and a robust and fast reconstruction of the spectral image data sets.

One form of embodiment of the method provides that two spectrally adjacent spectral volumes at least partially overlap in the spectral direction. The shape of the excitation pulses typically defines the profile of the excited frequency range, wherein for a rectangular profile a theoretically infinitely long excitation pulse would be required (SINC pulse). Consequently, the profiles actually achieved typically have a smooth progression. A spectral overlap of adjacent spectral volumes reduces signal loss and increases the redundancy of the data.

Furthermore, the disclosure is based on a magnetic resonance device with a control unit comprising a detection unit, a provision unit and a reconstruction unit. The control unit and/or the magnetic resonance device is designed to execute a method for multispectral magnetic resonance imaging.

The capture unit can be designed as an input, via which the raw data is provided to the control unit. The capture unit can be designed to acquire the raw data. For this purpose, the capture unit can have an input, via which the capture unit is provided with an MR control sequence specifying the sampling patterns. The capture unit can be designed to control the magnetic resonance device corresponding to the MR control sequence for the acquisition of the raw data, e.g. corresponding to the sampling patterns. The reconstruction unit is designed for the reconstruction of the spectral image data sets from the raw data and for the combination of the spectral image data sets to form image data. The provision unit is designed to provide the raw data and/or the image data.

Furthermore, the control unit typically has an input, a processor unit and an output. Via the input the control unit can be provided with further functions, algorithms or parameters required in the method. The provision unit can form the output. Further results of a form of embodiment of the method can be provided via the output. The control unit can be integrated into the magnetic resonance device. The control unit can also be installed separately from the magnetic resonance device. The control unit can be connected to the magnetic resonance device.

Forms of embodiment of the magnetic resonance device are designed analogously to the forms of embodiment of the method. The magnetic resonance device can have further control components which are necessary and/or advantageous for the execution of an method. The magnetic resonance device can also be designed to send control signals and/or receive and/or process control signals in order to execute any of the methods described herein. Computer programs and further software can be stored on a memory unit of the control unit, by means of which the processor unit of the control unit automatically controls and/or executes a sequence of any of the methods described herein.

A computer program product can be loaded directly in a memory unit of a programmable control unit and has program code means in order to execute any of the methods described herein if the computer program product is executed in the control unit. This allows the any of the methods described herein to be executed quickly, identically repeatably and robustly. The computer program product is configured so that by means of the control unit it can execute any of the method steps described herein. In this case the control unit must in each case have the preconditions such as for example a corresponding main memory, a corresponding graphics card or a corresponding logic unit, so that the respective method steps can be efficiently executed. The computer program product is for example stored on an electronically readable medium or on a network or server, from where it can be loaded into the processor of a local control unit which is directly connected to the magnetic resonance device or can be designed as part of the magnetic resonance device. Furthermore, control information from the computer program product can be stored on an electronically readable data carrier. The control information from the electronically readable data carrier can be configured such that it performs any of the methods described herein when using the data carrier in a control unit of a magnetic resonance device. Examples of electronically readable data carriers are a DVD, a magnetic tape or a USB stick, on which electronically readable control information, e.g. software, is stored. If this control information (software) is read by the data carrier and stored in a control unit of a magnetic resonance device, all forms of embodiment of the previously described methods can be performed.

Furthermore, the disclosure is based on an electronically readable data carrier on which a program is stored, which is intended for an execution of a method for multispectral magnetic resonance imaging.

The advantages of the magnetic resonance device, of the computer program product and of the electronically readable data carrier correspond substantially to the advantages of the method for multispectral magnetic resonance imaging, which are explained above in detail. Features, advantages or alternative forms of embodiment mentioned here can likewise be transferred to the other claimed subject matters and vice versa.

### BRIEF DESCRIPTION OF THE DRAWINGS

Further advantages, features and details of the disclosure emerge from the exemplary embodiments described below and on the basis of the drawings, in which:

FIG. 1 illustrates an example magnetic resonance device, in accordance with the present disclosure;

FIG. 2 illustrates an example flow diagram of a first method, in accordance with the present disclosure;

FIG. 3 illustrates an example flow diagram of a second method, in accordance with the present disclosure; and

FIG. 4 illustrates example sampling patterns for raw data sets and the reconstruction of the spectral image data sets, in accordance with the present disclosure.

### DETAILED DESCRIPTION OF THE DISCLOSURE

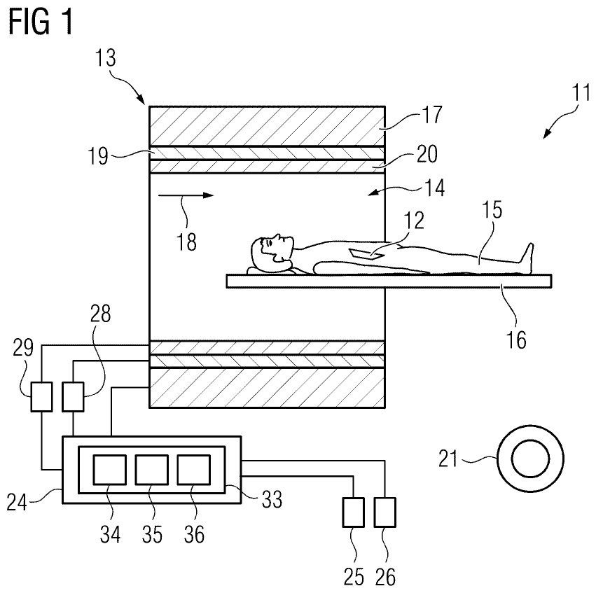

FIG. 1 illustrates an example magnetic resonance device, in accordance with the present disclosure. For instance, FIG. 1 shows a magnetic resonance device 11 for the execution of any of the methods as described herein. The magnetic resonance device 11 comprises a detector unit (also referred to herein as a detector or detector circuitry) formed from a magnet unit 13 (also referred to herein as a magnetic assembly) with a main magnet 17 for generating a strong and constant main magnetic field 18. Furthermore, the magnetic resonance device 11 has a cylindrical patient receiving area 14 for receiving an object under examination, e.g. a patient 15, wherein the patient receiving area 14 is cylindrically surrounded in a circumferential direction by the magnet unit 13. The patient 15 being examined in the context of the multispectral magnetic resonance imaging may have a metal implant 12 and may be pushed into the patient receiving area 14 by means of a patient positioning apparatus 16 of the magnetic resonance device 11. For this purpose, the patient positioning apparatus 16 has a patient table which is movably arranged inside the magnetic resonance device 11.

The magnet unit 13 further has a gradient coil unit 19 (also referred to herein as gradient coil circuitry or one or more gradient coils), which may be used for position encoding during imaging. The gradient coil unit 19 may be controlled by means of a gradient control unit 28 (also referred to herein as gradient control circuitry). Furthermore, the magnet unit 13 has a radio-frequency antenna unit 20 (also referred to herein as RF antenna circuitry or one or more antennas), which in the case shown is designed as a body coil permanently integrated into the magnetic resonance device 11, and a radio-frequency antenna control unit (also referred to herein as RF antenna control circuitry) 29 for an excitation of a polarization which occurs in the main magnetic field 18 generated by the main magnet 17. The radio-frequency antenna unit 20 may be controlled by the radio-frequency antenna control unit 29 and radiates high-frequency radio-frequency pulses into an examination space, which is substantially formed by the patient receiving area 14.

To control the main magnet 17, the gradient control unit 28 and the radio-frequency antenna control unit 29, the magnetic resonance device 11 has a main control unit 24 (also referred to herein as one or more processors, a controller, or a control computer). The main control unit 24 centrally controls the magnetic resonance device 11, such as for example the performance of MR control sequences.

The magnetic resonance device 11 has a display unit 25 (also referred to herein as a display or monitor). Control information such as for example control parameters, as well as reconstructed image data may be presented on the display unit 25, for example on at least one monitor, for a user. Furthermore, the magnetic resonance device 11 has an input unit 26 (also referred to herein as a user interface or input interface), by means of which information and/or control parameters can be input by a user during a scanning procedure. The main control unit 24 can comprise the gradient control unit 28 and/or radio-frequency antenna control unit 29 and/or the display unit 25 and/or the input unit 26.

Furthermore, the main control unit 24 comprises a control unit 33 (also referred to herein as one or more processors or a controller), comprising a capture unit 34 (also referred to herein as a capturer or capture circuitry), a provision unit 35 (also referred to herein as a provider or provision circuitry) and a reconstruction unit 36 (also referred to herein as a reconstructor or reconstruction circuitry). The control unit 33 is furthermore designed to execute a method for multispectral magnetic resonance imaging. For this purpose, the control unit 33 has computer programs and/or software which can be loaded directly in a memory unit (not shown in greater detail) of the control unit 33, with program means to execute a method for multispectral magnetic resonance imaging if the computer programs and/or software are executed in the control unit 33. For this purpose, the control unit 33 has a processor (not shown in greater detail) which is designed to execute the computer programs and/or software. Alternatively, the computer programs and/or software can also be stored on an electronically readable data carrier 21 designed separately from the main control unit 24 and/or control unit 33, wherein data can be accessed from the control unit 33 to the electronically readable data carrier 21 via a data network.

The magnetic resonance device 11 shown can of course comprise further components which magnetic resonance devices 11 usually have. A general functionality of a magnetic resonance device 11 is also known to the person skilled in the art, so that a detailed description of the further components is dispensed with. The magnetic resonance device 11 is thus designed together with the control unit 33 to execute any of the methods as described herein.

A method for multispectral magnetic resonance imaging can also be in the form of a computer program product which implements the method onto the control unit 33 if it is executed on the control unit 33. Likewise, an electronically readable data carrier 21 with electronically readable control information stored thereon can be present, which at least comprises such a computer program product just described and is configured such that it performs the method described when the data carrier 21 is used in a control unit 33 of a magnetic resonance device 11.

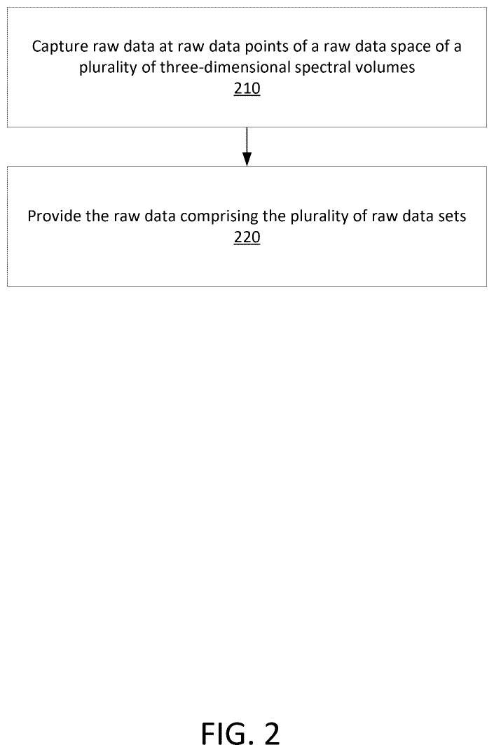

FIG. 2 illustrates an example flow diagram of a first method, in accordance with the present disclosure. FIG. 2 shows a flow diagram of a first example embodiment of a method for multispectral magnetic resonance imaging. Firstly, in method step 210, the capture of raw data 60 takes place at raw data points of a raw data space of a plurality of three-dimensional spectral volumes, said spectral volumes differing at least in their frequency range 51, 52, 53, 54 used for excitation, wherein the raw data 60 comprises a plurality of raw data sets 61, 62, 63, 64, in each case a raw data set is to be assigned to a spectral volume, each raw data set 61, 62, 63, 64 comprises raw data of a raw data space corresponding to a sampling pattern 71, 72, 73, 74, and the sampling patterns 71, 72, 73, 74 for raw data sets 61, 62, 63, 64 of two spectrally adjacent spectral volumes in each case are different from one another. The provision of the raw data 60 comprising the plurality of raw data sets 61, 62, 63, 64 takes place in method step 220.

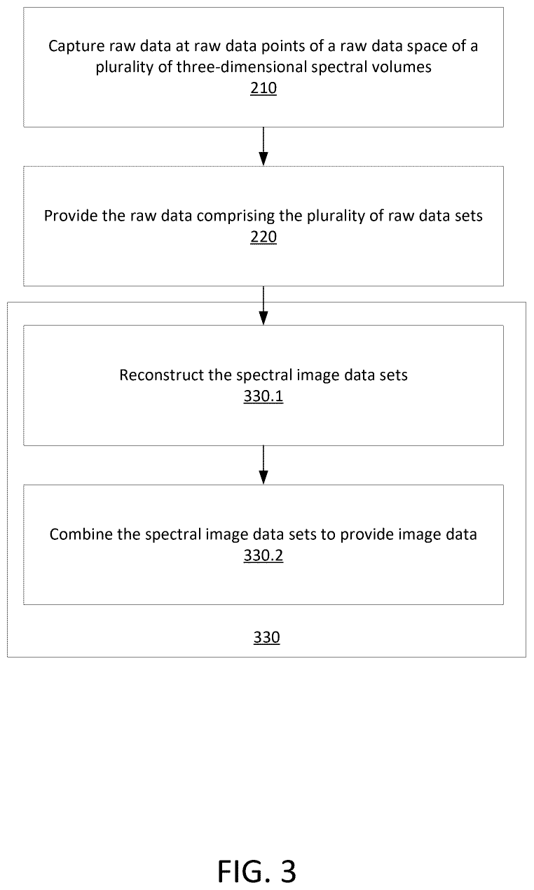

FIG. 3 illustrates an example flow diagram of a second method, in accordance with the present disclosure. FIG. 3 shows a flow diagram of a second example embodiment of a method for multispectral magnetic resonance imaging. The second example embodiment differs from the first example embodiment shown in FIG. 2 with respect to method step 330 for the reconstruction of the raw data 60 to form image data. For this, method step 330 comprises the method steps 330.1 and 330.2, wherein in method step 330.1 the reconstruction of the spectral image data sets 81, 82, 83, 84, and in method step 330.2 the combination of the spectral image data sets 81, 82, 83, 84 to form image data takes place. In method step 330.1, compressed sensing and/or a sparse transformation in the spectral direction and/or a trained function and/or a reconstruction method of parallel imaging can be used.

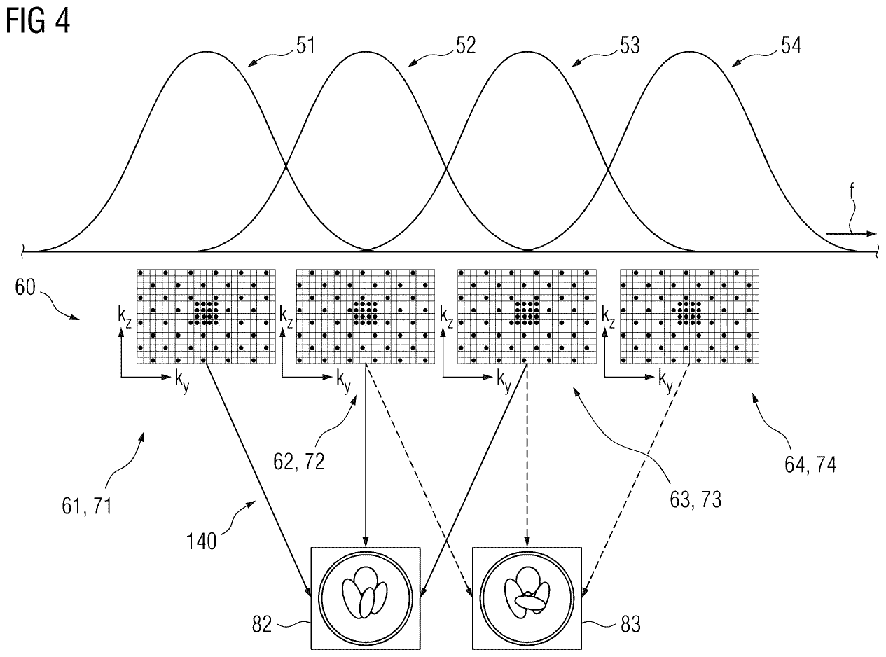

FIG. 4 illustrates example sampling patterns for raw data sets and the reconstruction of the spectral image data sets, in accordance with the present disclosure. FIG. 4 shows sampling patterns 71, 72, 73, 74 for raw data sets 61, 62, 63, 64 in accordance with an example embodiment of any of the methods as described herein, as well as the corresponding processing of the raw data 60 during the reconstruction of the spectral image data sets 81, 82, 83, 84 in accordance with method step 330.1 in a schematic representation.

The frequency ranges 51, 52, 53, 54 used for the excitation of the spectral volumes are shown in the spectral direction f, i.e. in their spectral sequence. The profiles of the frequency ranges 51, 52, 53, 54 are bell-shaped or Gauss-shaped in the form of embodiment shown and overlap at least partially. Assigned to the frequency ranges 51, 52, 53, 54 used for the excitation of the spectral volumes, the corresponding sampling patterns 71, 72, 73, 74 for raw data sets 61, 62, 63, 64 are shown below: the raw data space is represented two-dimensionally for each raw data set, where ky specifies the first phase-encoding direction and kz the second phase-encoding direction. Not shown in greater detail is the perpendicular frequency-encoding direction kx, whereby in this direction kx raw data is typically sampled quickly and in full. The grid specifies the raw data space in each case for each raw data set 61, 62, 63, 64 in the spectral direction f, wherein the sampling patterns 71, 72, 73, 74 and/or the positions of the raw data sets 61, 62, 63, 64 are marked as points in the raw data space.

In the form of embodiment shown the sampling patterns 71, 72, 73, 74 each have an undersampling by a factor of 4 in the first phase-encoding direction ky and an undersampling by a factor of 2 in the second phase-encoding direction kz, thus in total an undersampling by a factor of 8. Furthermore, the sampling pattern has a phase offset in the first phase-encoding direction ky and in the spectral direction f: the sampling patterns 71, 73 are each configured identically and the sampling patterns 72, 74 are each configured identically. The sampling patterns 71, 72 have a phase offset to one another in the spectral direction f and are shifted to one another by two raw data points in the first phase-encoding direction ky. For instance, the sampling patterns 71, 72 have an offset to one another in the spectral direction f, in which for the undersampling the grid and/or raster is shifted by two raw data points in the first phase-encoding direction ky. The sampling patterns 73, 74 have a phase offset to one another in the spectral direction f and are shifted to one another by two raw data points in the first phase-encoding direction ky. In this case, the undersampling in each case takes place in a peripheral area of the raw data space.

The central area of the raw data space is sampled in full for all sampling patterns 71, 72, 73, 74 in accordance with this form of embodiment. In accordance with an alternative form of embodiment (not shown in greater detail) an undersampling of the central area can also take place, for example by a factor of 2 or 4.

In accordance with method step 330.1, spectral image data sets 81, 82, 83, 84 are reconstructed for the spectral volumes, whereby this is visualized by way of example for the spectral image data sets 82, 83: based on the raw data sets 61, 62, 63, the spectral image data set 82 is reconstructed and based on the raw data sets 62, 63, 64 the spectral image data set 83 is reconstructed. Not shown in greater detail is method step 330.2, in accordance with which the spectral image data sets 82, 83, for example all spectral image data sets 81, 82, 83, 84, are combined to form image data.

Although the disclosure has been illustrated and described in greater detail by the exemplary embodiments, the disclosure is nevertheless not restricted by the disclosed examples and other variations can be derived therefrom by the person skilled in the art, without departing from the scope of protection of the disclosure. Independent of the grammatical term usage, individuals with male, female or other gender identities are included within the term.

Additionally, the various components described herein may be referred to as “units.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units, etc., as applicable and relevant, may alternatively be referred to herein as “circuitry,” “controllers,” “processors,” or “processing circuitry,” or alternatively as noted herein.

What is claimed is:

1. A method for multispectral magnetic resonance imaging, comprising:
capturing raw data at raw data points of a raw data space associated with a plurality of three-dimensional (3D) spectral volumes,
wherein each one of the plurality of 3D spectral volumes differs at least in a frequency range used for excitation,
wherein the raw data comprises a plurality of raw data sets, each one of the plurality of raw data sets being assigned to a respective spectral volume of the plurality of 3D spectral volumes,
wherein each one of the plurality of raw data sets corresponds to a respective one of a plurality of sampling patterns, and
wherein ones of the plurality of sampling patterns associated with raw data sets of two spectrally adjacent spectral volumes are different from one another; and
providing the raw data comprising the plurality of raw data sets.

2. The method as claimed in claim 1, wherein the plurality of sampling patterns provide for undersampling in two phase-encoding directions with a phase offset in one phase-encoding direction of the two phase-encoding directions and a phase offset in a spectral direction,
wherein the spectral direction corresponds to a spectral sequence of the plurality of 3D spectral volumes.

3. The method as claimed in claim 2, wherein the plurality of sampling patterns in a peripheral area of raw data space of the corresponding raw data sets in the spectral direction differ from one another by a translation in the raw data space.

4. The method as claimed in claim 2,
wherein a number P of the plurality of sampling patterns are provided for the raw data space, and are repeated in the spectral direction corresponding to the spectral sequence after P spectral volumes.

5. The method as claimed in claim 3, wherein the sampling patterns of the raw data sets in the peripheral area of the raw data space provide for undersampling by a factor of at least four.

6. The method as claimed in claim 3, wherein the sampling patterns of the raw data sets in the peripheral area of the raw data space provide for undersampling by an identical factor.

7. The method as claimed in claim 1, wherein the sampling patterns of the raw data sets in a central area of the raw data space provide for undersampling.

8. The method as claimed in claim 1, further comprising:
reconstructing the raw data to form image data by, for each one of the plurality of 3D spectral volumes, reconstructing and combining the corresponding spectral image data sets to form the image data.

9. The method as claimed in claim 8, wherein reconstructing the corresponding spectral image data sets for each spectral volume comprises using raw data sets associated with the spectral volume and the at least one spectrally adjacent spectral volume.

10. The method as claimed in claim 8, wherein the reconstruction of the corresponding spectral image data sets for each spectral volume uses compressed sensing and/or a sparse transformation in the spectral direction and/or a trained function.

11. The method as claimed in claim 8, wherein the reconstruction of the corresponding spectral image data sets for each spectral volume uses a reconstruction method of parallel imaging.

12. The method as claimed in claim 1, wherein the raw data sets of the two spectrally adjacent spectral volumes overlap at least partially in the spectral direction.

13. A magnetic resonance device, comprising:
a receiving area configured to receive an object under examination; and
control circuitry configured to perform multispectral magnetic resonance imaging by:
capturing raw data at raw data points of a raw data space associated with a plurality of three-dimensional (3D) spectral volumes,
wherein each one of the plurality of 3D spectral volumes differs at least in a frequency range used for excitation,
wherein the raw data comprises a plurality of raw data sets, each one of the plurality of raw data sets being assigned to a respective spectral volume of the plurality of 3D spectral volumes,
wherein each one of the plurality of raw data sets corresponds to a respective one of a plurality of sampling patterns, and
wherein ones of the plurality of sampling patterns associated with raw data sets of two spectrally adjacent spectral volumes are different from one another; and
providing the raw data comprising the plurality of raw data sets.

14. A non-transitory computer-readable medium having instructions stored thereon that, when executed by control circuitry of a magnetic resonance imaging device, cause the magnetic resonance imaging device to perform multispectral magnetic resonance imaging by:
capturing raw data at raw data points of a raw data space associated with a plurality of three-dimensional (3D) spectral volumes,
wherein each one of the plurality of 3D spectral volumes differs at least in a frequency range used for excitation,
wherein the raw data comprises a plurality of raw data sets, each one of the plurality of raw data sets being assigned to a respective spectral volume of the plurality of 3D spectral volumes,
wherein each one of the plurality of raw data sets corresponds to a respective one of a plurality of sampling patterns, and
wherein ones of the plurality of sampling patterns associated with raw data sets of two spectrally adjacent spectral volumes are different from one another; and
providing the raw data comprising the plurality of raw data sets.
